(19) United States
(12) Patent Application Publication
(10) Pub. No.: US 2006/0284310 A1
(43) Pub. Date: Dec. 21, 2006

(54) Offset via on pad

(76) Inventors: Jeffrey A. Hall, San Jose, CA (US); Shahram Nikoukary, San Jose, CA (US)

Correspondence Address: LSI LOGIC CORPORATION, 1621 BARBER LANE, MS: D-106, MILPITAS, CA, 95035, US

(21) Appl. No.: 11/153,915

(22) Filed: Jun. 15, 2005

(51) Int. Cl. H01L 23/48

(52) U.S. Cl. 257/734

(57) ABSTRACT

A printed circuit board with an electrically conductive bonding pad disposed on an outer surface of the printed circuit board. The bonding pad has a bonding pad perimeter at immediately bounding edges of the bonding pad. An electrically conductive via directly electrically contacts the bonding pad, and is disposed within the printed circuit board relative to the bonding pad. The via has a via perimeter at immediately bounding edges of the via. The via perimeter overlaps the pad perimeter such that a portion of the via perimeter is within the pad perimeter and a portion of the via perimeter is outside the pad perimeter. In various embodiments, the bonding pad is a ball bonding pad.

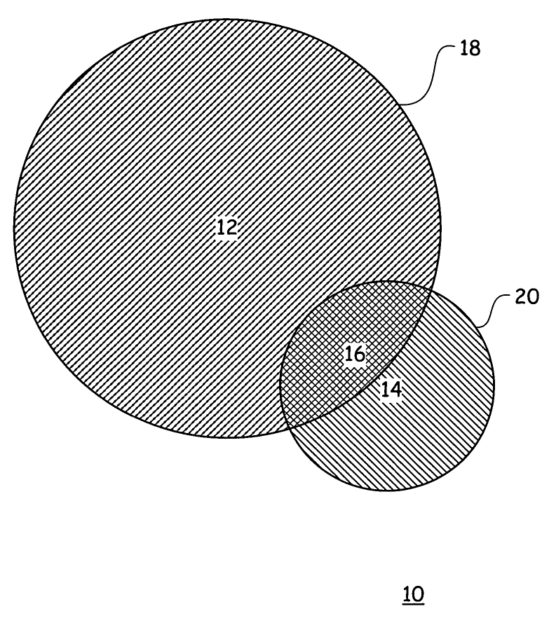

### FIELD

This invention relates to the field of integrated circuit fabrication. More particularly, this invention relates to forming electrically conductive via connections to contact pads in a variety of microelectronic applications.

### BACKGROUND

As the term is used herein, “integrated circuit” includes devices such as those formed on monolithic semiconducting substrates, such as those formed of group IV materials like silicon or germanium, or group III-V compounds like gallium arsenide, or mixtures of such materials. The term includes all types of devices formed, such as memory and logic, and all designs of such devices, such as MOS and bipolar. The term also comprehends applications such as flat panel displays, solar cells, and charge coupled devices.

Modern integrated circuits require a great number of connections in order to electrically communicate with other circuits. For example, functional elements within the monolithic structure itself need to be routed out to a banding pad of some type, whether it be a solder bump pad or a wire bonding pad. These are then connected to a package substrate, which also has pads on its mating surface that are electrically connected to vias that lead to routing structures within the package substrate. Typically, the package substrate will also have vias that connect to pads on the opposing side of the package substrate also, which pads may take a variety of forms, such as solder ball pads. These pads are then in turn further electrically connected to pads on a printed circuit board, which are also electrically connected to vias within them, which route the signals through the printed circuit board.

Traditionally, the position for a given pad and the position for its associated via could not overlap. The via either had to be completely outside of a given pad or completely contained within a given pad. Thus, much of the space underneath the pad was considered to be unusable space. There were reasons why this design rule was implemented, and at a time when structures such as package substrates and printed circuit boards were not particularly limited by usable space, this design rule did not cause any particular problems.

However, as circuit densities have increased and the size of circuit structures has decreased, structures such as package substrates and printed circuit boards have become very limited by usable space. What is needed, therefore, is a system that overcomes problems such as those described above, at least in part.

### SUMMARY

The above and other needs are met by a printed circuit board with an electrically conductive bonding pad disposed on an outer surface of the printed circuit board. The bonding pad has a bonding pad perimeter at immediately bounding edges of the bonding pad. An electrically conductive via directly electrically contacts the bonding pad, and is disposed within the printed circuit board relative to the bonding pad. The via has a via perimeter at immediately bounding edges of the via. The via perimeter overlaps the pad perimeter such that a portion of the via perimeter is within the pad perimeter and a portion of the via perimeter is outside the pad perimeter. In various embodiments, the bonding pad is a ball bonding pad.

In this manner, the various embodiments according to the present invention provide additional space in which elements such as vias can be disposed within the structure. In the past, the space along the perimeter of the bonding pad could not be used because of design rules. However, according to the present invention, the perimeter of the via overlaps the perimeter of the bonding pad to at least some degree. Thus, the placement of the via relative to the bonding pad can be moved all around the perimeter of the bonding pad, and in and out from the center of the bonding pad, so long as the perimeters overlap, with a portion of the via perimeter extending outside of the bonding pad perimeter and a portion of the via perimeter extending inside of the bonding pad perimeter.

According to another aspect of the invention there is described a package substrate with an electrically conductive bonding pad disposed on an outer surface of the package substrate. The bonding pad has a pad perimeter at immediately bounding edges of the bonding pad. An electrically conductive via directly electrically contacts the bonding pad, and is disposed within the package substrate relative to the bonding pad. The via has a via perimeter at immediately bounding edges of the via. The via perimeter overlaps the pad perimeter such that a portion of the via perimeter is within the pad perimeter and a portion of the via perimeter is outside the pad perimeter.

In various embodiments according to this aspect of the invention, the bonding pad is at least one of a ball bonding pad, a bump bonding pad, and a wire bonding pad.

### BRIEF DESCRIPTION OF THE DRAWINGS

Further advantages of the invention are apparent by reference to the detailed description when considered in conjunction with the FIGURE, which is not to scale so as to more clearly show the details, wherein like reference numbers indicate like elements, and which is a top view depiction of the relative alignment between a bonding pad and a via according to a preferred embodiment of the invention.

### DETAILED DESCRIPTION

With reference now to the FIGURE, there is depicted a portion of a substrate 10, which in various embodiments may be either a printed circuit board or a package substrate. Disposed on an exterior surface of the substrate 10 there is a bonding pad 12. The bonding pad 12 is, in various embodiments, a ball bonding pad, a bump bonding pad, a wire bonding pad, or some other type of electrical connection pad 12 as known in the relevant art. The purpose of the bonding pad 12 is to expose an electrical contact point by which an electrical connection to the substrate 10 can be made.

The substrate 10 also includes a via 14. The FIGURE indicates the relative positions of the bonding pad 12 and via 14 as depicted from a view of the surface of the substrate 10. It is appreciated that in actual implementation only a portion of the via 14, or alternately none of the via 14 at all, would be visible from the surface of the substrate 10. The reason for this is not because all of the via 14 would be disposed under the bonding pad 12, but rather because in many embodiments there would be a layer disposed around the bonding pad 12 that would cover the via 14. Such a covering layer is not depicted in the FIGURE, so as to more clearly show the more relevant aspects of the present invention.

The bonding pad 12 has a perimeter 18, and the via 14 has a perimeter 20. According to the present invention, the perimeter 18 of the bonding pad 12 overlaps the perimeter 20 of the via 14, such that some of via 14 is disposed outside of the perimeter 18 of the bonding pad 12, but some of the via 14, specifically the overlapping portion 16 as depicted in the FIGURE, is disposed within the perimeter 18 of the bonding pad 12. In no embodiment of the present invention is the via 14 entirely within or merely touching from inside the perimeter 18 of the bonding 12, or entirely outside or merely touching from outside the perimeter 18 of the bonding pad 12.

Thus, the portion 16 of the via 14 that is within the perimeter 18 of the bonding pad 12 may be greater than or less than that generally depicted in the FIGURE, the portion 16 always exists, within the embodiments of the present invention. This provides a tremendous degree of latitude in placing the via 14 relative to the bonding pad 12, by allowing it to be shifted around the perimeter 18 of the bonding pad 12, and also by allowing it to be moved in and out in radial directions from the center of the bonding pad 12, enlarging or reducing the area of the overlapping portion 16 as desired, so long as the perimeters 18 and 20 of the bonding pad 12 and the via 14 overlap, as described above.

According to the present invention, the via 14 directly electrically contacts the bonding pad 12, within the use of an intermediate structure such as an electrically conductive trace. Thus, all of the electrical connection between the bonding pad 12 and the via 14 is made by the overlapping area 16. In some embodiments the bonding pad is a passive component bonding pad, where the passive components include at least one of a resistor, a capacitor, and an inductor.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A printed circuit board, comprising:
an electrically conductive bonding pad disposed on an outer surface of the printed circuit board, the bonding pad having a bonding pad perimeter at immediately bounding edges of the bonding pad, and
an electrically conductive via directly electrically contacting the bonding pad and disposed within the printed circuit board relative to the bonding pad, the via having a via perimeter at immediately bounding edges of the via,
where the via perimeter overlaps the pad perimeter such that a portion of the via perimeter is within the pad perimeter and a portion of the via perimeter is outside the pad perimeter.

2. The printed circuit board of claim 1, wherein the bonding pad is a ball bonding pad.

3. The printed circuit board of claim 1, wherein the bonding pad is a passive component bonding pad, where the passive components include at least one of a resistor, a capacitor, and an inductor.

4. The printed circuit board of claim 1, wherein the bonding pad is a wire bonding pad.

5. A package substrate, comprising:
an electrically conductive bonding pad disposed on an outer surface of the package substrate, the bonding pad having a pad perimeter at immediately bounding edges of the bonding pad, and
an electrically conductive via directly electrically contacting the bonding pad and disposed within the package substrate relative to the bonding pad, the via having a via perimeter at immediately bounding edges of the via,
where the via perimeter overlaps the pad perimeter such that a portion of the via perimeter is within the pad perimeter and a portion of the via perimeter is outside the pad perimeter.

6. The package substrate of claim 5, wherein the bonding pad is a ball bonding pad.

7. The package substrate of claim 5, wherein the bonding pad is a bump bonding pad.

8. The package substrate of claim 5, wherein the bonding pad is a wire bonding pad.

9. The package substrate of claim 5, wherein the bonding pad is a passive component bonding pad, where the passive components include at least one of a resistor, a capacitor, and an inductor.
